(19) United States
(12) Patent Application Publication
(10) Pub. No.: US 2010/0020599 A1
(43) Pub. Date: Jan. 28, 2010

(54) MULTI-LEVEL FLASH MEMORY

(75) Inventors: LIH WEI LIN, CHIAYI COUNTY (TW); WEI SHENG HSU, YILAN COUNTY (TW); YAN RU YANG, TAOYUAN COUNTY (TW); YEN WEN CHEN, HSINCHU CITY (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., HSINCHU (TW)

(21) Appl. No.: 12/178,174

(22) Filed: Jul. 23, 2008

(51) Int. Cl. G11C 16/04

(52) U.S. Cl. 365/185.03

(57) ABSTRACT

A multi-level flash memory comprises a semiconductor substrate, a gate structure having a lower block positioned in the semiconductor substrate and an upper block positioned on the semiconductor substrate, and a plurality of storage structures separated by the gate structure. The upper block connects to the lower block of the gate structure, and each of the storage structures includes a charge-trapping site and an insulation structure surrounding the charge-trapping site.

### BACKGROUND OF THE INVENTION

(A) Field of the Invention

The present invention relates to a multi-level flash memory and method for preparing the same, and more particularly, to a multi-level flash memory with the storage structures separated by the gate structure and method for preparing the same.

(B) Description of the Related Art

Flash memory has been widely applied to the data storage of digital products such as laptop computers, digital assistants, cell phones, digital cameras, digital recorders, and MP3 players. Recently, a flash memory comprises a silicon-oxide-nitride-oxide-silicon (SONOS) structure, which is widely used in flash memory since it possesses the advantages of a thinner memory cell and a simpler fabrication process.

FIG. 53 shows a memory cell 100 described in U.S. Pat. No. 6,011,725. The memory cell 100 includes diffused source/drain regions 120A and 120B in a semiconductor substrate 110, a gate insulator 130 overlying the semiconductor substrate 110, and a gate 150 overlying the gate insulator 130. The gate insulator 130 has an ONO structure including a silicon nitride layer 140 sandwiched between silicon dioxide layers 132 and 134. Two bits of data are stored in memory cell 100 as charges that are trapped in charge-trapping regions 140A and 140B in the silicon nitride layer 140. Each region 140A or 140B corresponds to a bit having a value 0 or 1 according to the state of the trapped charges at the region 140A and 140B.

The memory cell 100 has the advantage of providing non-volatile storage of two bits of information in a single-transistor memory cell, increasing the storage density over that of a memory device storing one bit of data per storage transistor. However, scaling the memory cell 100 down to smaller sizes may present difficulties. In particular, operation of the memory cell 100 requires the ability to inject charges into separate regions 140A and 140B in the silicon nitride layer 140. As the width of the silicon nitride layer 140 decreases, the distance between locations 140A and 140B may become too short, which may result in merging of the regions 140A and 140B.

### SUMMARY OF THE INVENTION

One aspect of the present invention provides a multi-level flash memory and method for preparing the same with the storage structures separated by the gate structure to prevent the storage structures from being merged as the size of the flash memory is reduced.

A multi-level flash memory according to this aspect of the present invention comprises a semiconductor substrate, a recessed gate positioned in the semiconductor substrate, an oxide layer sandwiched between the recessed gate and the semiconductor substrate, and a plurality of storage structures separated by the recessed gate, where each of the storage structures includes a charge-trapping site and an insulation structure surrounding the charge-trapping site.

Another aspect of the present invention provides a multi-level flash memory comprising a semiconductor substrate, a gate structure having a lower block positioned in the semiconductor substrate and an upper block positioned on the semiconductor substrate, and a plurality of storage structures separated by the gate structure. The upper block connects to the lower block of the gate structure, and each of the storage structures includes a charge-trapping site and an insulation structure surrounding the charge-trapping site.

As the size of the flash memory is reduced, the distance between the charge-trapping regions of the conventional flash memory may become too small, which in the prior art may result in merging of the charge-trapping regions. In contrast, the storage structures of the present invention are separated by the upper block or the bottom block of the gate structure; therefore, the storage structures are prevented from merging, even as the size of the flash memory is reduced.

Another aspect of the present invention provides a method for preparing a multi-level flash memory comprising the steps of forming a recess in a semiconductor substrate, forming a plurality of storage structures at the sides of the recess, and forming a gate structure having a lower block in the recess and an upper block on the lower block. The storage structures are separated by the gate structure, and each of the storage structures includes a charge-trapping site and an insulation structure surrounding the charge-trapping site.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention will become apparent upon reading the following description and upon reference to the accompanying drawings in which:

FIG. 1 to FIG. 15 illustrate a method for preparing a multi-level flash memory according to one embodiment of the present invention;

FIG. 16 and FIG. 17 illustrate a method for preparing a multi-level flash memory according to another embodiment of the present invention;

FIG. 18 to FIG. 33 illustrate a method for preparing a multi-level flash memory according to another embodiment of the present invention;

FIG. 34 and FIG. 35 illustrate a method for preparing a multi-level flash memory according to another embodiment of the present invention;

FIG. 36 to FIG. 50 illustrate a method for preparing a multi-level flash memory according to another embodiment of the present invention;

FIG. 51 and FIG. 52 illustrate a method for preparing a multi-level flash memory according to another embodiment of the present invention; and

FIG. 53 shows a memory cell according to the prior art.

### DETAILED DESCRIPTION OF THE INVENTION

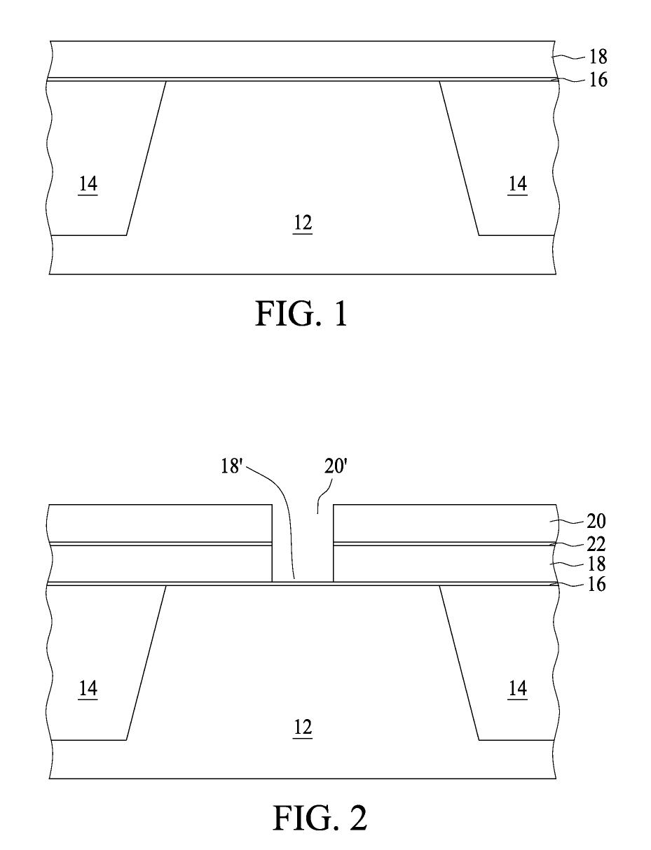

FIG. 1 to FIG. 15 illustrate a method for preparing a multi-level flash memory 10A according to one embodiment of the present invention. First, a semiconductor substrate 12 such as a P-type semiconductor substrate with a shallow trench isolation (STI) 14 undergoes a thermal oxidation process to form a pad oxide layer 16 on the surface of the semiconductor substrate 12, and a polysilicon layer 18 is then formed on the pad oxide layer 16 by the deposition process. Subsequently, a lithographic process is performed to form a photoresist layer 20 with an opening 20′ on the polysilicon layer 18, and a dry etching process is then performed to remove a portion of the polysilicon layer 18 under the opening 20′ of the photoresist layer 20 to form an opening 18′ in the polysilicon layer 18, as shown in FIG. 2. In particular, an anti-reflection layer 22 is sandwiched between the polysilicon layer 18 and the photoresist layer 20, and the pad oxide layer 16 is used as an etching stop layer for the dry etching process to form the opening 18′.

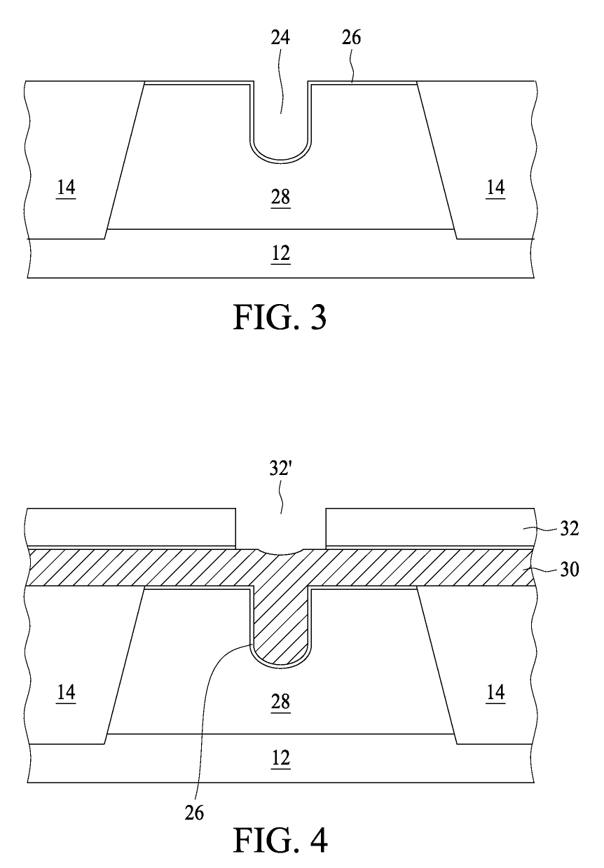

Referring to FIG. 3, the photoresist layer 20 and the anti-reflection layer 22 are stripped, and the polysilicon layer 18 is used as a hard mask to perform a dry etching process, which removes a portion of the semiconductor substrate 12 under the opening 18′ to form a recess 24 in the semiconductor substrate 12. After the polysilicon layer 18 is stripped, a thermal oxidation process is performed to form an oxide layer 26 on the surface of the semiconductor substrate 12 and on the inner sidewall of the recess 24. Subsequently, P-type dopants are then implanted into the semiconductor substrate 12 to form a P-well 28 in the semiconductor substrate 12 between the shallow trench isolation 14.

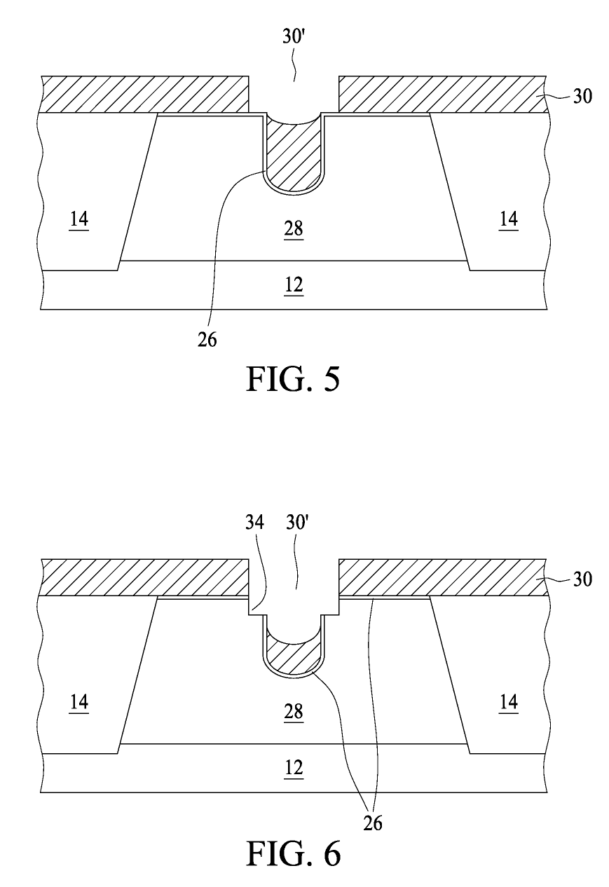

Referring to FIG. 4, a polysilicon layer 30 is formed on the semiconductor substrate 12, and a photoresist layer 32 with an opening 32′ larger than the recess 24 is then formed on the polysilicon layer 30 by the lithographic process. Subsequently, a dry etching process is then performed to remove a portion of the polysilicon layer 30 under the opening 32′ to form an aperture 30′ in the polysilicon layer 30, and the photoresist layer 32 is stripped, as shown in FIG. 5.

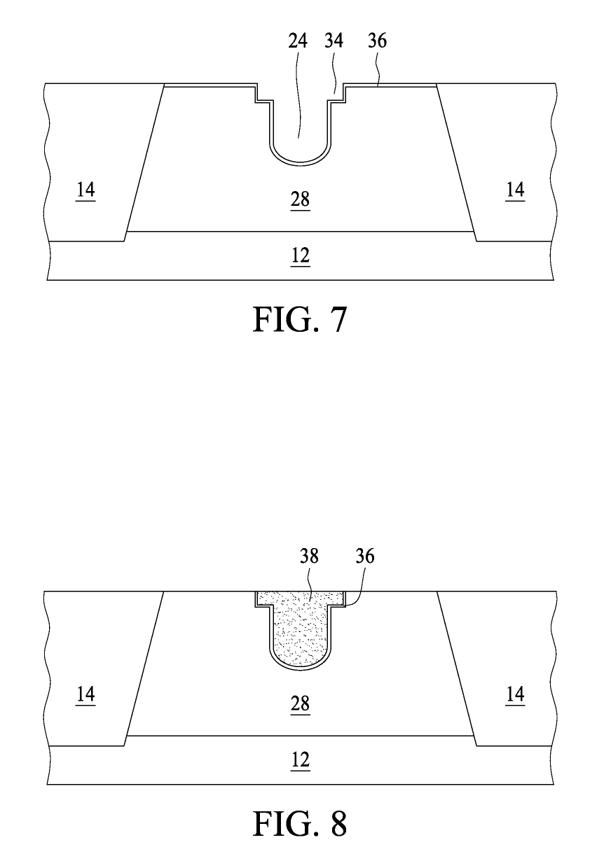

Referring to FIG. 6, the polysilicon layer 30 is used as a hard mask to perform a dry etching process, which removes a portion of the semiconductor substrate 12 under the opening 30′ such that an upper portion of the recess 24 is enlarged to form an enlarged area 34. Subsequently, the polysilicon layer 32 and the oxide layer 26 are stripped, and the oxidation process is performed to form an oxide layer 36 on the surface of the semiconductor substrate 12, on the inner sidewall of the recess 24 and on the surface of the enlarged area 34, as shown in FIG. 7.

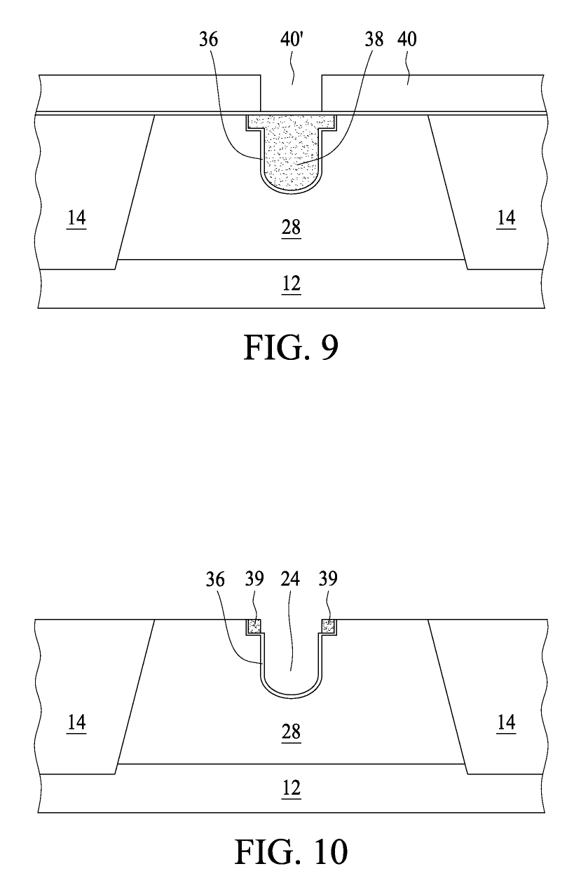

Referring to FIG. 8, a charge-trapping layer 38 filling the recess 24 and the enlarged area 34 is formed by a deposition process followed by a planarization process such as the chemical mechanical polishing process. The charge-trapping layer 38 may include silicon nitride or polysilicon. Subsequently, an etching mask 40 such as a photoresist layer with an aperture 40′ is then formed on the semiconductor substrate 12, as shown in FIG. 9. In particular, the aperture 40′ is formed on the recess 24 and is smaller than the enlarged area 34.

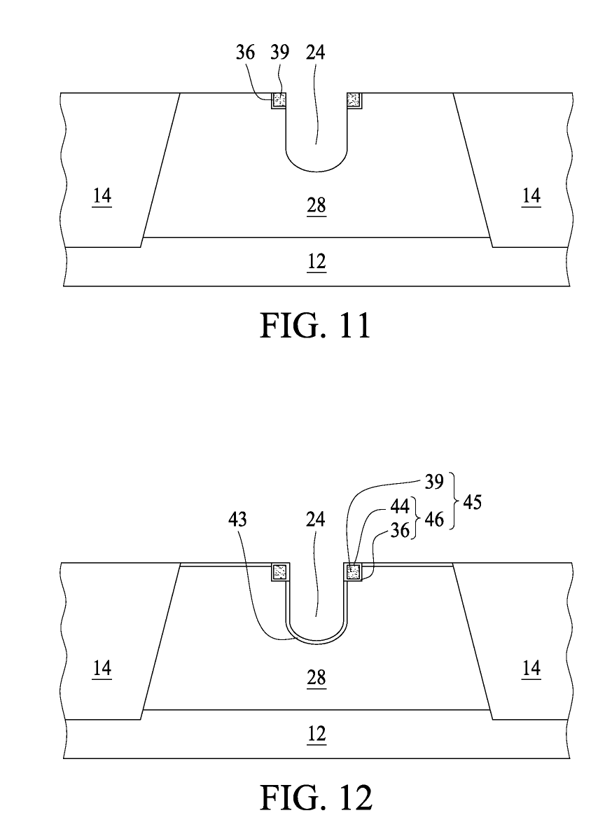

Referring to FIG. 10, a dry etching process is performed using the etching mask 40 to remove a portion of the charge-trapping layer 38 from the recess 24 through the aperture 40′ such that the other portion of the charge-trapping layer 38 forms a plurality of charge-trapping sites 39 in the enlarged area 34 at the sides of the upper portion of the recess 24 in the semiconductor substrate 12. Subsequently, a portion of the oxide layer 36 on the inner sidewall of the recess 24 is stripped, while the other portion of the oxide layer 36 covered by the charge-trapping site 39 is not stripped, as shown in FIG. 11.

Referring to FIG. 12, an oxidation process, such as an in-situ steam generated (ISSG) process or a thermal oxidation process, is performed to form an oxide layer 44 such as silicon-oxy-nitride layer or silicon oxide layer on the exposed surface of the charge-trapping sites 39 and a tunnel oxide layer 43 on the inner sidewall of the recess 24. The oxide layer 36 and the oxide layer 44 together form an insulation structure 46 surrounding the charge-trapping sites 39, and each of the charge-trapping site 39 and the insulation structure 46 surrounding the charge-trapping site 39 form a storage structure 45.

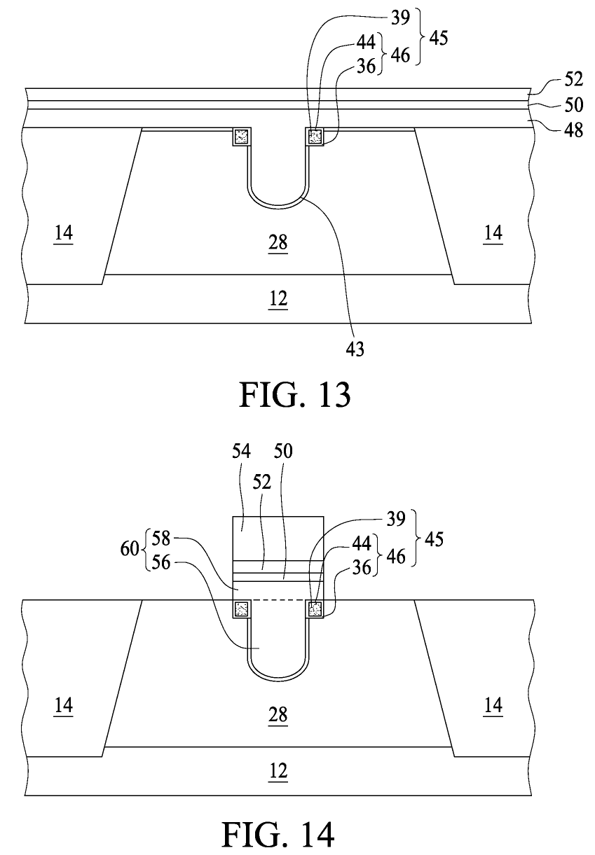

Referring to FIG. 13, a polysilicon layer 48 doped with N-type dopants is formed by a deposition process followed by a planarization process such as the chemical mechanical polishing process, and a tungsten silicide layer 50 and a silicon nitride layer 52 are then formed on the polysilicon layer 48. Subsequently, a mask 54 such as a photoresist layer is formed on the silicon nitride layer 52 by the lithographic process, and a dry etching process is then performed to remove a portion of the polysilicon layer 48, the tungsten silicide layer 50 and the silicon nitride layer 52 not covered by the mask 54 to form a T-shaped gate structure 60, as shown in FIG. 14. In particular, the T-shaped gate structure 60 includes a lower block 56 in the P-well 28 of the semiconductor substrate 12 and an upper block 58 on the P-well 28 of the semiconductor substrate 12. Furthermore, the lower block 56 of the T-shaped gate structure 60 serves as a recessed gate, while the remaining polysilicon layer 48 and tungsten silicide layer 50 together with the upper block 58 form a word line.

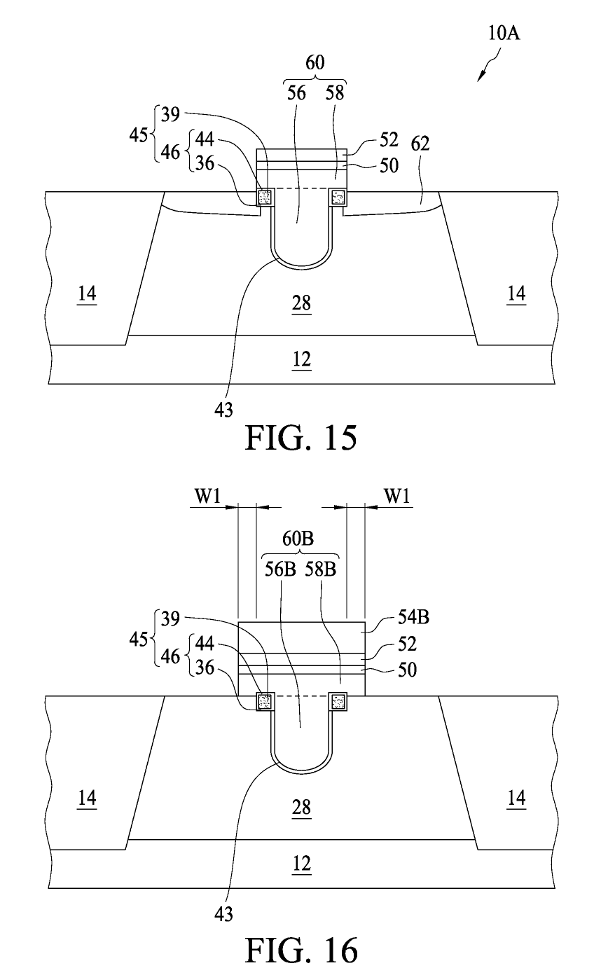

Referring to FIG. 15, the mask 54 is stripped, and an implanting process is then performed to implant N-type dopants into a portion of the P-well 28 to form a plurality of doped regions 62 serving as the source and the drain at the sides of the T-shaped gate structure 60 so as to complete the multi-level flash memory 10A. In particular, the upper block 56 connects to the lower block 58 of the T-shaped gate structure 60. Furthermore, the storage structures 45 are separated by the lower block 56 (recessed gate) of the T-shaped gate structure 60, the charge-trapping site 39 is positioned below the upper block 58 of the T-shaped gate structure 60, and the doped regions 62 contact the insulation structure 46. The multi-level flash memory 10A can use channel hot electron injection (CHEI) mechanism to conduct the programming of the cell, use the band-to-band (BTBT) hot hole enhanced injection (HHEI) mechanism to conduct the erasing of the cell, use the reversed read mechanism to conduct the reading of the cell.

As the size of the flash memory is reduced, the distance between the charge-trapping regions 140A and 140B of the conventional flash memory 100 may become too small, which may result in merging of the charge-trapping regions 140A and 140B as in to the prior art. In contrast, the storage structures 45 of the flash memory 10A are separated by the lower block 56 of the T-shaped gate structure 60; therefore, the storage structures 45 are prevented from merging even as the size of the flash memory 10A is reduced.

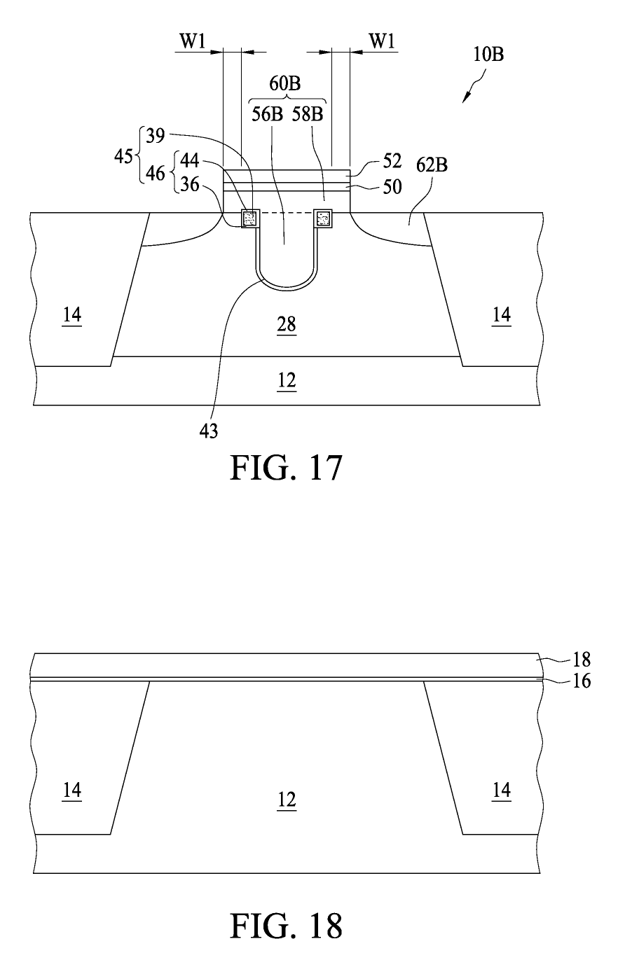

FIG. 16 and FIG. 17 illustrate a method for preparing a multi-level flash memory 10B according to another embodiment of the present invention. The fabrication processes shown in FIG. 1 to FIG. 13 are performed, a mask 54B is formed on the silicon nitride layer 52 by the lithographic process, and a dry etching process is then performed to remove a portion of the polysilicon layer 48, the tungsten silicide layer 50 and the silicon nitride layer 52 not covered by the mask 54B to form a T-shaped gate structure 60B including a lower block 56B in the P-well 28 of the semiconductor substrate 12 and an upper block 58B on the P-well 28 of the semiconductor substrate 12. Subsequently, the mask 54B is stripped, and an implanting process is then performed to implant N-type dopants into a portion of the P-well 28 to form a plurality of doped regions 62B serving as the source and the drain at the sides of the T-shaped gate structure 60B so as to complete the multi-level flash memory 10B, as shown in FIG. 17.

In particular, the lateral width of the mask 54B in FIG. 16 is larger than that of the mask 54 in FIG. 14 by 2×W1. Therefore, the lateral width of the T-shaped gate structure 60B in FIG. 16 is increased by 2×W1, as compared to the T-shaped gate structure 60 in FIG. 14. Consequently, the doped regions 62B are separated from the insulation structure 46 by the semiconductor substrate 12, and the channel length of the multi-level flash memory 10B in FIG. 17 is larger than that of the multi-level flash memory 10A in FIG. 15 by 2×W1. In particular, The multi-level flash memory 10B can use channel hot electron injection (CHEI) mechanism to conduct the programming of the cell, use the band-to-band (BTBT) hot hole enhanced injection (HHEI) mechanism to conduct the erasing of the cell, use the reversed read mechanism to conduct the reading of the cell.

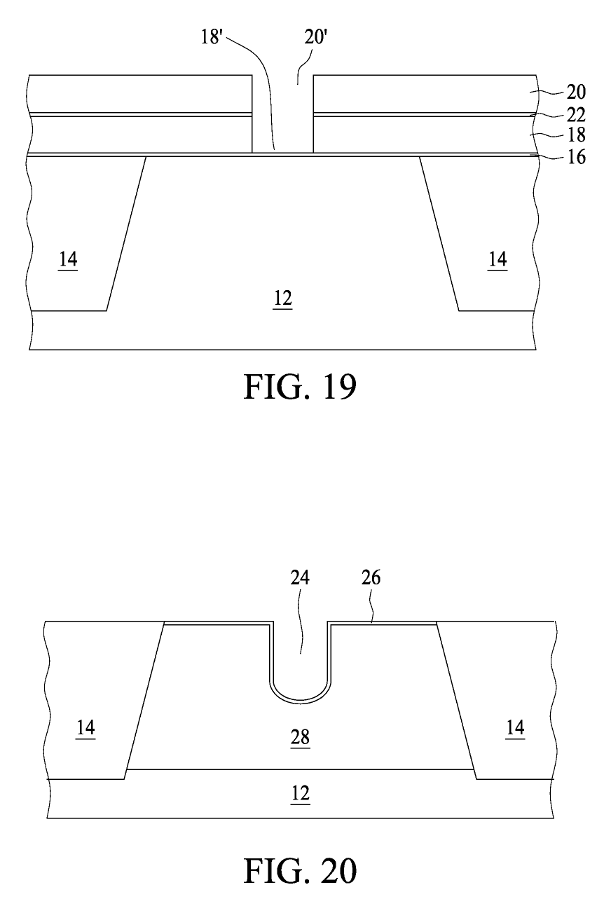

FIG. 18 to FIG. 33 illustrate a method for preparing a multi-level flash memory 10C according to another embodiment of the present invention. First, a semiconductor substrate 12 such as a P-type silicon substrate with a shallow trench isolation 14 undergoes a thermal oxidation process to form a pad oxide layer 16 on the surface of the semiconductor substrate 12, and a polysilicon layer 18 is then formed on the pad oxide layer 16 by the deposition process. Subsequently, a lithographic process is performed to form a photoresist layer 20 with an opening 20′ on the polysilicon layer 18, and a dry etching process is then performed to remove a portion of the polysilicon layer 18 under the opening 20′ of the photoresist layer 20 to form an opening 18′ in the polysilicon layer 18, as shown in FIG. 19. In particular, an anti-reflection layer 22 is sandwiched between the polysilicon layer 18 and the photoresist layer 20, and the pad oxide layer 16 is used as an etching stop layer for the dry etching process to form the opening 18′.

Referring to FIG. 20, the photoresist layer 20 and the anti-reflection layer 22 are stripped, and the polysilicon layer 18 is used as a hard mask to perform a dry etching process, which removes a portion of the semiconductor substrate 12 under the opening 18′ to form a recess 24 in the semiconductor substrate 12. After the polysilicon layer 18 is stripped, a thermal oxidation process is performed to form an oxide layer 26 on the surface of the semiconductor substrate 12 and on the inner sidewall of the recess 24. Subsequently, P-type dopants are implanted into the semiconductor substrate 12 to form a P-well 28 in the semiconductor substrate 12 between the shallow recess isolation 14.

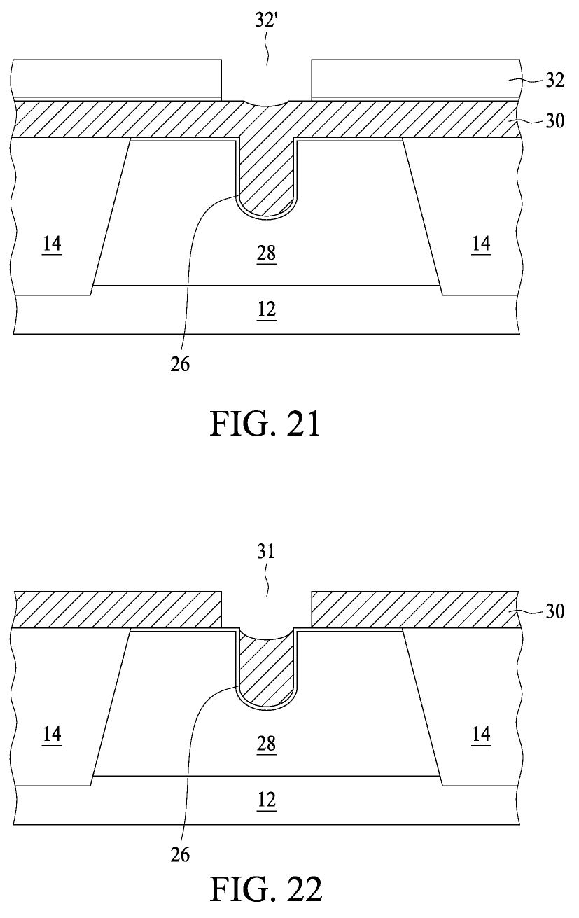

Referring to FIG. 21, a polysilicon layer 30 is formed on the semiconductor substrate 12, and a photoresist layer 32 with an opening 32′ larger than the recess 24 is then formed on the polysilicon layer 30 by the lithographic process. Subsequently, a dry etching process is then performed by using the oxide layer 26 as the etching stop layer to remove a portion of the polysilicon layer 30 under the opening 32′ of the photoresist layer 32 to form an aperture 31 in the polysilicon layer 30, and the photoresist layer 32 is stripped, as shown in FIG. 22.

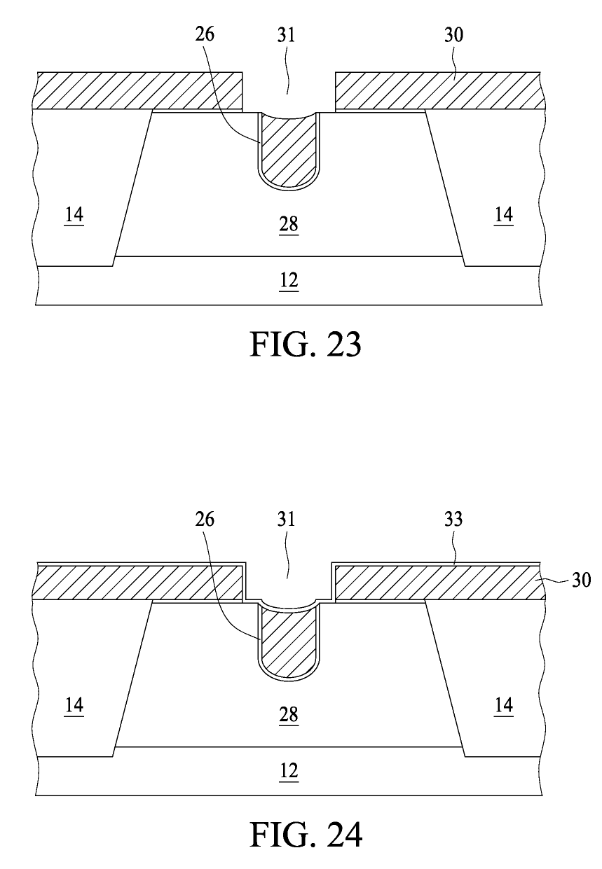

Referring to FIG. 23, an etching process is performed by using the polysilicon layer 30 as an etching mask to remove a portion of the oxide layer 26 from the surface of the semiconductor substrate 12 under the aperture 31 of the polysilicon layer 30. Subsequently, an oxide layer 33 is formed on the surface of the semiconductor substrate 12 under the aperture 31 and on the surface of the polysilicon layer 30 by an oxidation process such as the thermal oxidation process, as shown in FIG. 24. The dry etching process to form the aperture 31 in the polysilicon layer 30 uses the oxide layer 26 as the etching stop layer, which is not suitable for electrical isolation of the charge-trapping site since it is damaged by the etching gases. Consequently, the damaged portion of the oxide layer 26 on the surface of the semiconductor substrate 12 under the aperture 31 of the polysilicon layer 30 is removed, and the new oxide layer 33 is then formed to serve as the electrical isolation of the subsequently formed charge-trapping site.

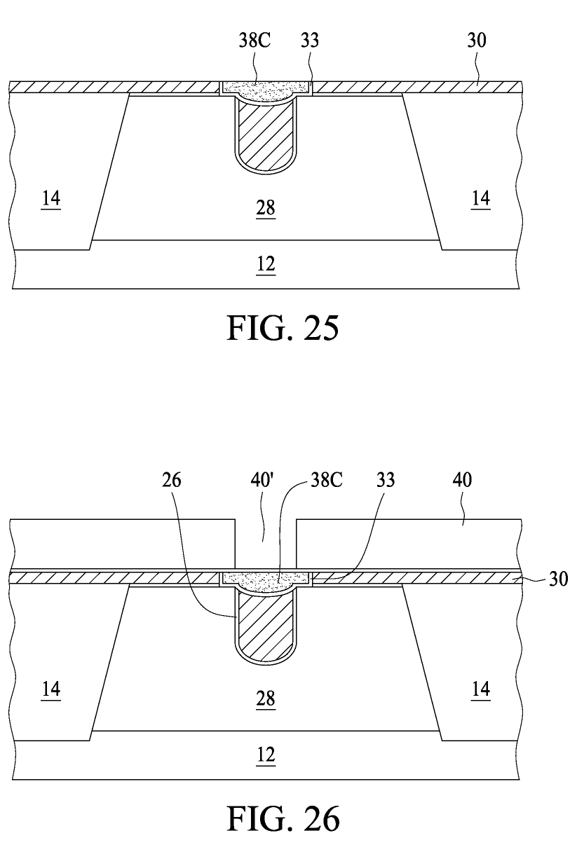

Referring to FIG. 25, a charge-trapping layer 38C filling the aperture 31 of the polysilicon layer 30 is formed by the deposition process followed by a planarization process such as the chemical mechanical polishing process. The charge-trapping layer 38C may include silicon nitride or polysilicon. Subsequently, an etching mask 40 such as a photoresist layer with an aperture 40′ is then formed on the semiconductor substrate 12 by the lithographic process, as shown in FIG. 26. In particular, the aperture 40′ is formed on the recess 24 and is smaller than the aperture 31 of the polysilicon layer 30.

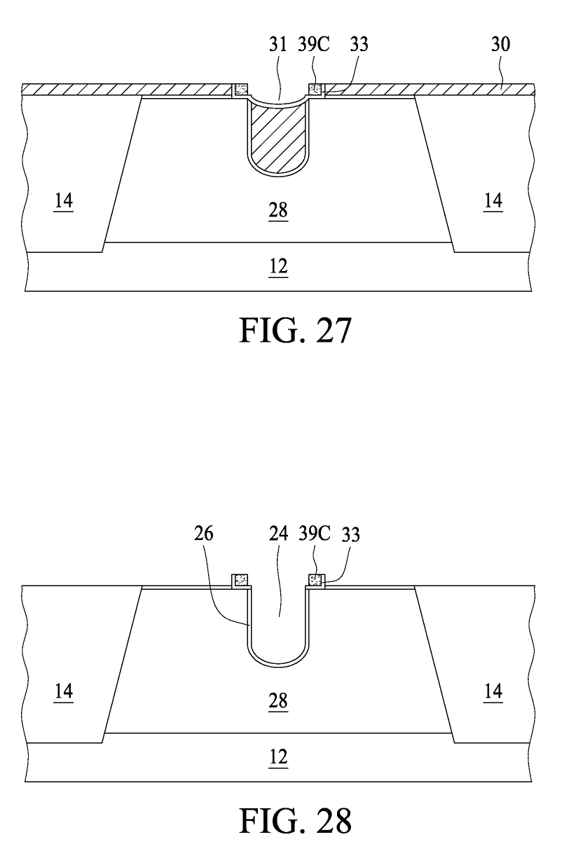

Referring to FIG. 27, a dry etching process is performed to remove a portion of the charge-trapping layer 38C under the aperture 40′ of the etching mask 40 such that the other portion of the charge-trapping layer 38C forms a plurality of charge-trapping sites 39C in the aperture 31 on the semiconductor substrate 12 at the sides of the recess 24. Subsequently, the etching mask 40 is stripped, and the polysilicon layer 30 is then removed from the surface of the semiconductor substrate 12 and the recess 24, as shown in FIG. 28. In particular, since the charge-trapping layer 38C is formed on the P-well 28 of the semiconductor substrate 12, the charge-trapping sites 39C are formed on the semiconductor substrate 12.

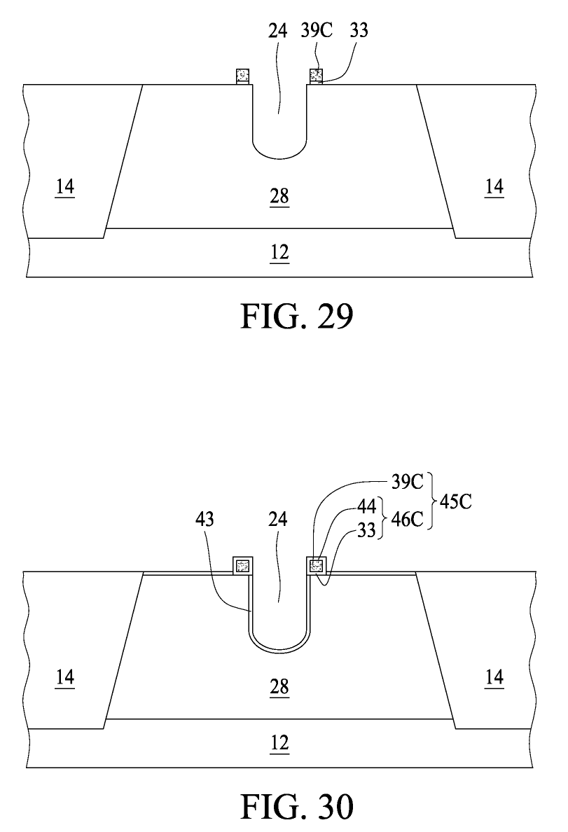

Referring to FIG. 29, an oxide stripping process is performed to remove the oxide layer 26 from the inner sidewall of the recess 24 and from the surface of the semiconductor substrate 12, and a portion of the oxide layer 33 from the sidewall of the charge-trapping sites 39C, while the other portion of the oxide layer 33 covered by the charge-trapping sites 39C is not stripped. Subsequently, an oxidation process, such as an in-situ steam generated (ISSG) process or a thermal oxidation process, is performed to form an oxide layer 44 such as silicon-oxy-nitride layer or silicon oxide layer on the exposed surface of the charge-trapping sites 39C and a tunnel oxide layer 43 on the inner sidewall of the recess 24, as shown in FIG. 30. The oxide layer 33 and the oxide layer 44 together form an insulation structure 46C surrounding the charge-trapping sites 39C, and each of the charge-trapping site 39C and the insulation structure 46C surrounding the charge-trapping site 39C form a storage structure 45C.

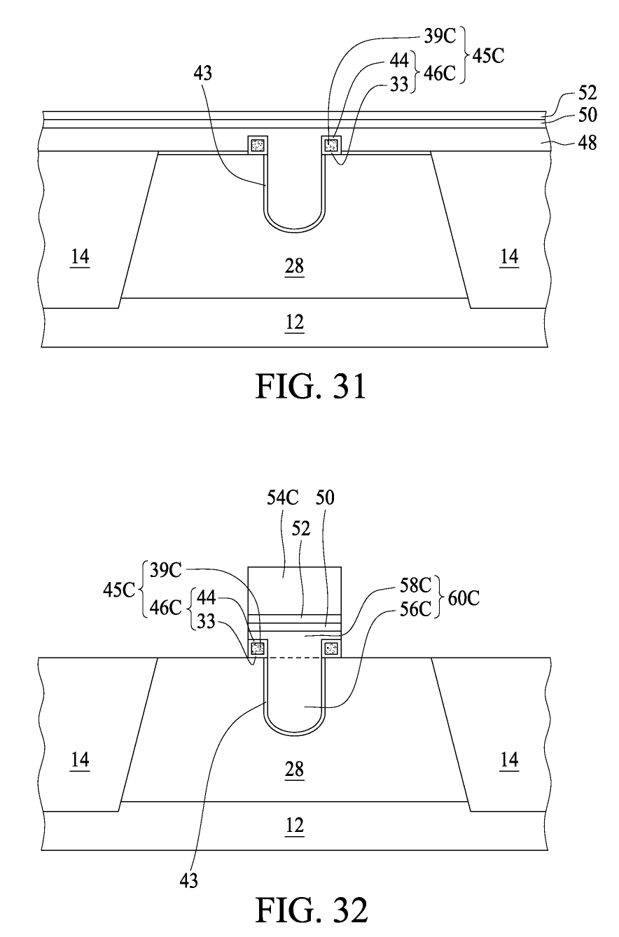

Referring to FIG. 31, a polysilicon layer 48 doped with N-type dopants is formed by a deposition process followed by a planarization process such as the chemical mechanical polishing process, and a tungsten silicide layer 50 and a silicon nitride layer 52 are then formed on the polysilicon layer 48. Subsequently, a photoresist layer 54C is formed on the silicon nitride layer 52 by the lithographic process, and a dry etching process is then performed to remove a portion of the polysilicon layer 48, the tungsten silicide layer 50 and the silicon nitride layer 52 not covered by the photoresist layer 54C to form a T-shaped gate structure 60C, as shown in FIG. 32. In particular, the T-shaped gate structure 60C includes a lower block 56C in the P-well 28 of the semiconductor substrate 12 and an upper block 58C on the P-well 28 of the semiconductor substrate 12. Furthermore, the lower block 56C of the T-shaped gate structure 60C serves as a recessed gate, while the remaining polysilicon layer 48 and tungsten silicide layer 50 together with the upper block 58C form a word line.

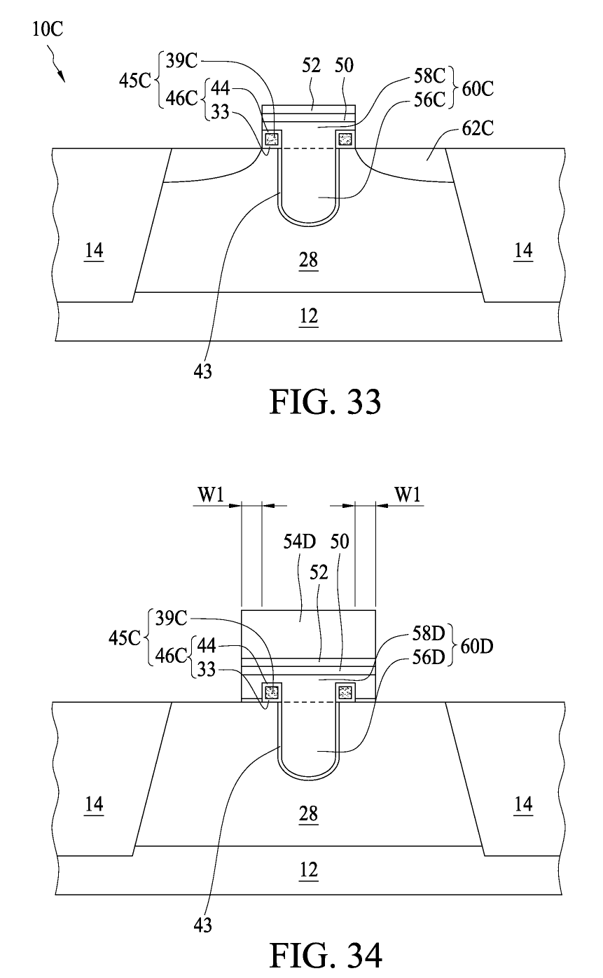

Referring to FIG. 33, the photoresist layer 54C is stripped, and an implanting process is then performed to implant N-type dopants into the P-well 28 to form a plurality of doped regions 62C serving as the source and the drain at the sides of the T-shaped gate structure 60C so as to complete the multi-level flash memory 10C. In particular, the upper block 58C connects to the lower block 56C of the T-shaped gate structure 60C. Furthermore, the storage structures 45C are separated and covered by upper block 58C of the T-shaped gate structure 60C, and the doped region 62C contacts the insulation structure 46C. The multi-level flash memory 10C can use channel hot electron injection (CHEI) mechanism to conduct the programming of the cell, use the band-to-band (BTBT) hot hole enhanced injection (HHEI) mechanism to conduct the erasing of the cell, use the reversed read mechanism to conduct the reading of the cell.

As the size of the flash memory is reduced, the distance between the charge-trapping regions 140A and 140B of the conventional flash memory 100 may become too small, which in the prior art may result in merging of the charge-trapping regions 140A and 140B. In contrast, the storage structures 45C of the flash memory 10C are separated by the upper block 58C of the T-shaped gate structure 60C; therefore, the storage structures 45C are prevented from merging even as the size of the flash memory 10C is reduced.

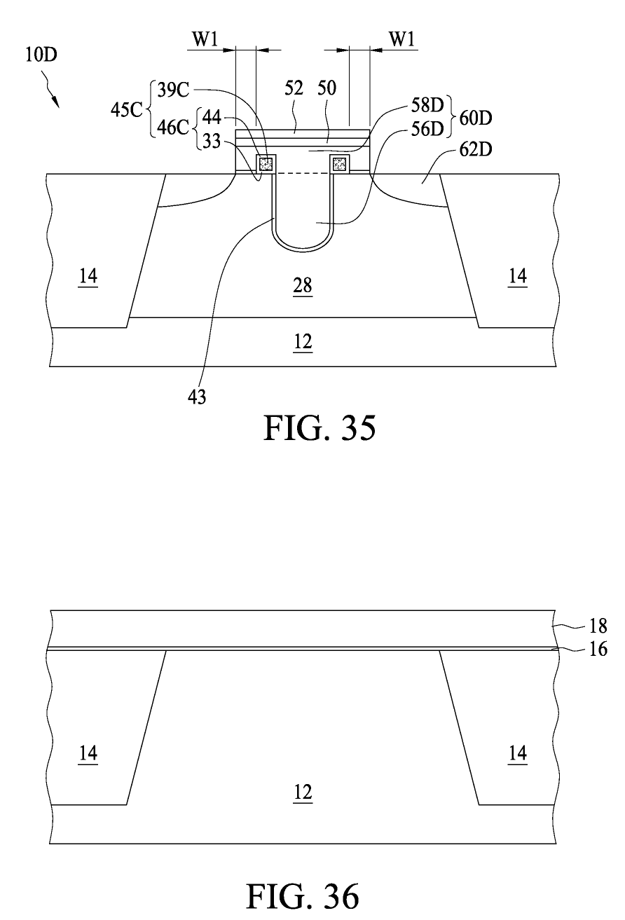

FIG. 34 and FIG. 35 illustrate a method for preparing a multi-level flash memory 10D according to another embodiment of the present invention. The fabrication processes shown in FIG. 18 to FIG. 31 are performed, a photoresist layer 54D is formed on the silicon nitride layer 52 by the lithographic process, and a dry etching process is then performed to remove a portion of the polysilicon layer 48, the tungsten silicide layer 50 and the silicon nitride layer 52 not covered by the photoresist layer 54D to form a T-shaped gate structure 60D including a lower block 56D in the semiconductor substrate 12 and an upper block 58D on the semiconductor substrate 12. Subsequently, the photoresist layer 54D is stripped, and an implanting process is then performed to implant N-type dopants into the P-well 28 to form a plurality of doped regions 62D serving as the source and the drain at the sides of the T-shaped gate structure 60D so as to complete the multi-level flash memory 10D, as shown in FIG. 35.

In particular, the lateral width of the photoresist layer 54D in FIG. 34 is larger than that of the photoresist layer 54C in FIG. 32 by 2×W1. Therefore, the lateral width of the T-shaped gate structure 60D in FIG. 34 is increased by 2×W1 as compared to that of the T-shaped gate structure 60C in FIG. 32. Consequently, the regions 62D are separated from the insulation structure 46C by the semiconductor substrate 12, and the channel length of the multi-level flash memory 10D in FIG. 35 is larger than that of the multi-level flash memory 10D in FIG. 33 by 2×W1. The multi-level flash memory 10A can use channel hot electron injection (CHEI) mechanism to conduct the programming of the cell, use the band-to-band (BTBT) hot hole enhanced injection (HHEI) mechanism to conduct the erasing of the cell, use the reversed read mechanism to conduct the reading of the cell.

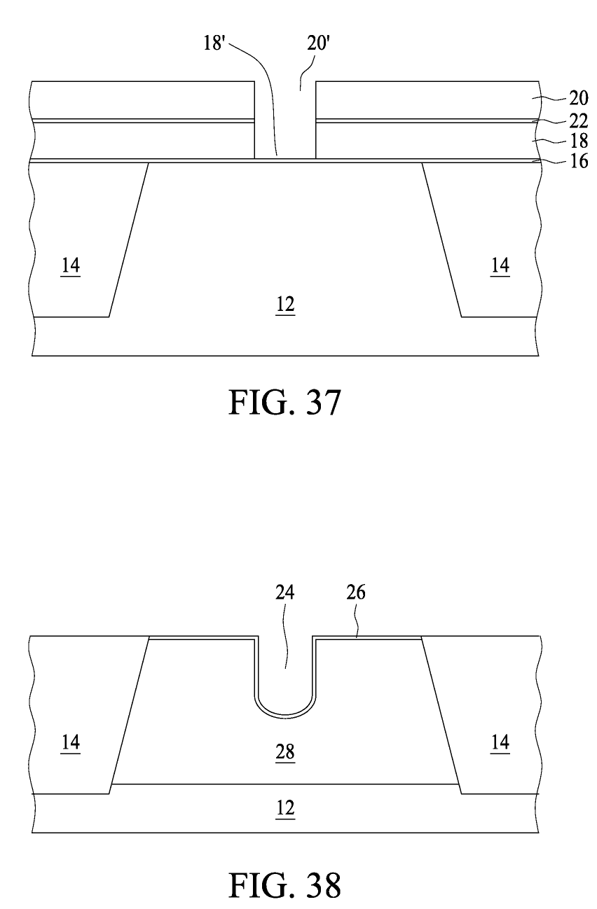

FIG. 36 to FIG. 50 illustrate a method for preparing a multi-level flash memory 10E according to another embodiment of the present invention. First, a semiconductor substrate 12 such as a P-type silicon substrate with a shallow trench isolation 14 undergoes a thermal oxidation process to form a pad oxide layer 16 on the surface of the semiconductor substrate 12, and a polysilicon layer 18 is then formed on the pad oxide layer 16 by the deposition process. Subsequently, a lithographic process is performed to form a photoresist layer 20 with an opening 20′ on the polysilicon layer 18, and a dry etching process is then performed to remove a portion of the polysilicon layer 18 under the opening 20′ of the photoresist layer 20 to form an opening 18′ in the polysilicon layer 18, as shown in FIG. 37. In particular, an anti-reflection layer 22 is sandwiched between the polysilicon layer 18 and the photoresist layer 20, and the pad oxide layer 16 is used as an etching stop layer for the dry etching process to form the opening 18′.

Referring to FIG. 38, the photoresist layer 20 and the anti-reflection layer 22 are stripped, and the polysilicon layer 18 is used as a hard mask to perform a dry etching process, which removes a portion of the semiconductor substrate 12 under the opening 18′ to form a recess 24 in the semiconductor substrate 12. After the polysilicon layer 18 is stripped, an oxide layer 26 is formed on the surface of the semiconductor substrate 12 and on the inner sidewall of the recess 24 by the oxidation process. Subsequently, P-type dopants are then implanted into the semiconductor substrate 12 to form a P-well 28 in the semiconductor substrate 12 between the shallow trench isolation 14.

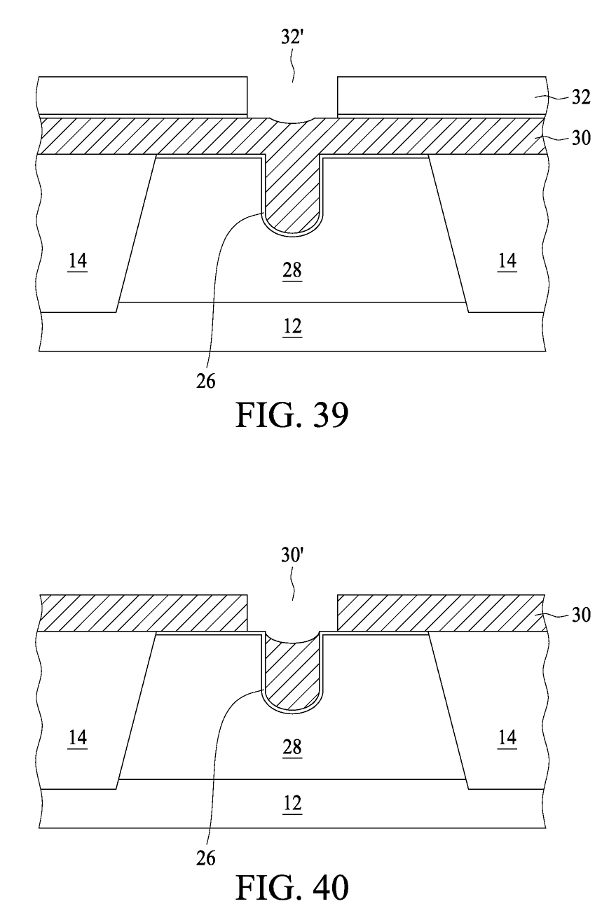

Referring to FIG. 39, a polysilicon layer 30 is formed on the semiconductor substrate 12, and a photoresist layer 32 with an opening 32′ larger than the recess 24 is then formed on the polysilicon layer 30 by the lithographic process. Subsequently, a dry etching process is performed by using the oxide layer 26 as the etching stop layer to remove a portion of the polysilicon layer 30 under the opening 32′ of the photoresist layer 32 to form an opening 30′ in the polysilicon layer 30, and the photoresist layer 32 is stripped, as shown in FIG. 40.

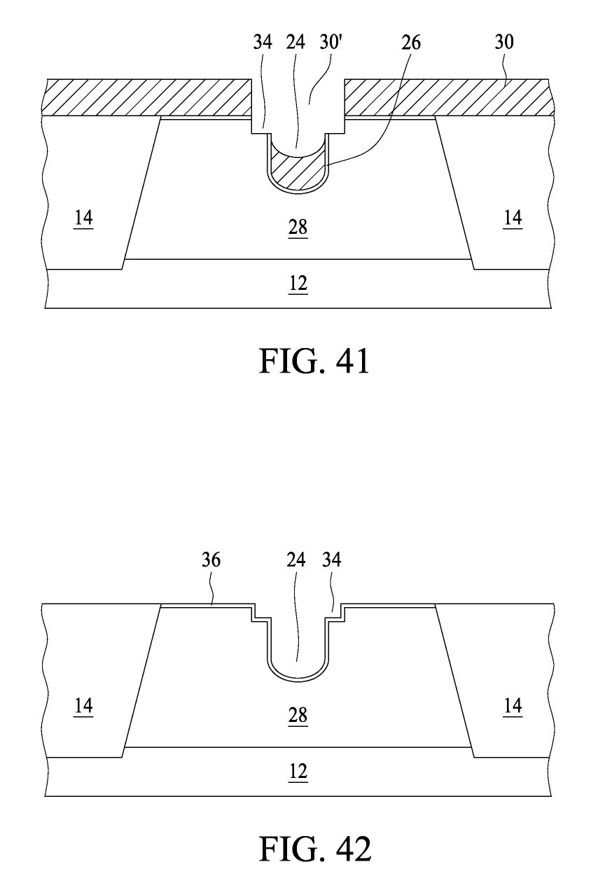

Referring to FIG. 41, the polysilicon layer 30 is used as a hard mask to perform a dry etching process, which removes a portion of the semiconductor substrate 12 under the opening 30′ such that an upper portion of the recess 24 is enlarged to form an enlarged area 34. Subsequently, the polysilicon layer 30 and the oxide layer 26 are stripped, and an oxide layer 36 is formed on the surface of the semiconductor substrate 12, on the inner sidewall of the recess 24, and on the surface of the enlarged area 34 by the oxidation process, as shown in FIG. 42.

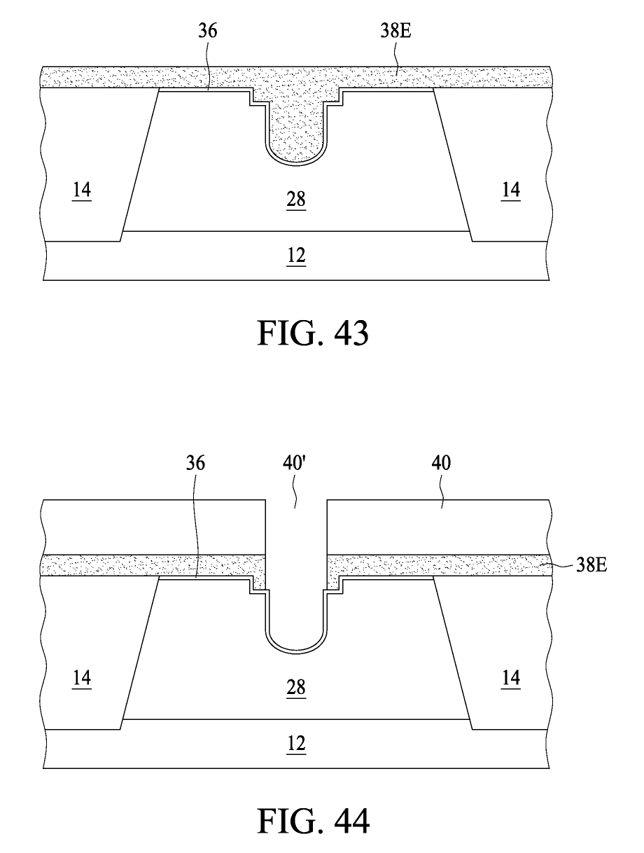

Referring to FIG. 43, a charge-trapping layer 38E filling the recess 24 and the enlarged area 34 is formed by a deposition process followed by a planarization process such as the chemical mechanical polishing process. The charge-trapping layer 38E may include silicon nitride or polysilicon. Subsequently, an etching mask 40 such as a photoresist layer with an aperture 40′ smaller than the enlarged area 34 is formed on the semiconductor substrate 12, and a dry etching process is performed using the etching mask 40 to remove a portion of the charge-trapping layer 38E under the aperture 40′ by using the oxide layer 36 as the etching stop layer, as shown in FIG. 44.

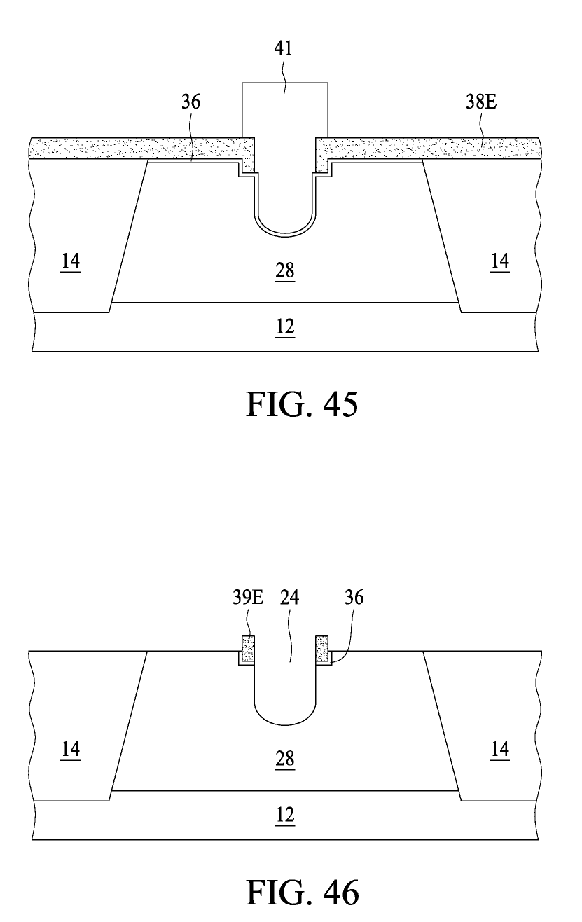

Referring to FIG. 45, the etching mask 40 is stripped, and another etching mask 41 filling the recess 24 and covering the enlarged area 34 is formed on the charge-trapping layer 38E. A dry etching process is then performed by using the oxide layer 36 as the etching stop layer to remove a portion of the charge-trapping layer 38E not covered by the etching mask 41 such that the other portion of the charge-trapping layer 38E forms two charge-trapping sites 39E in the enlarged area 34 at the sides of the recess 24. Subsequently, a stripping process is performed to remove the etching mask 41 and an exposed portion of the oxide layer 36, while the other portion of the oxide layer 36 covered by the two charge-trapping sites 39E is not stripped, as shown in FIG. 46.

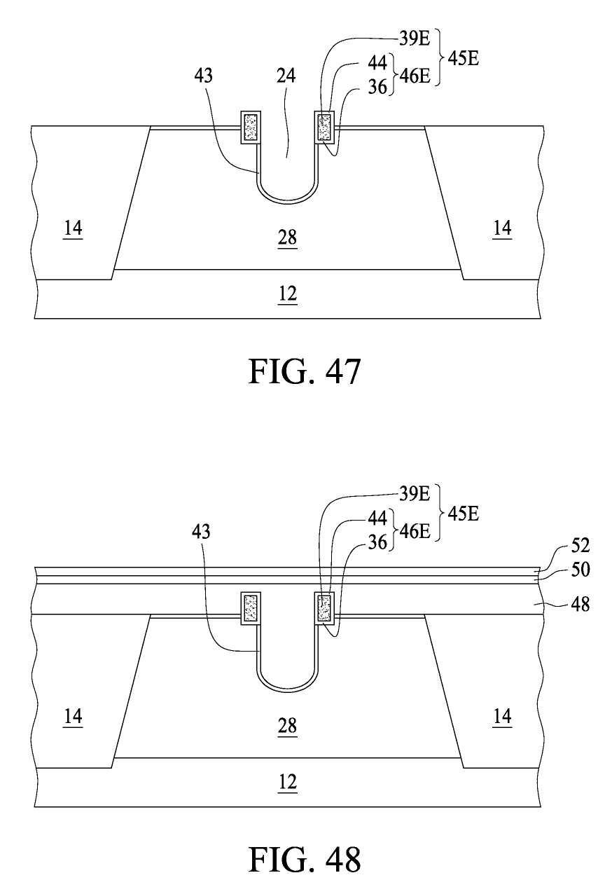

Referring to FIG. 47, an oxidation process, such as an in-situ steam generated (ISSG) process or a thermal oxidation process, is performed to form an oxide layer 44 such as silicon-oxy-nitride layer or silicon oxide layer on the exposed surface of the two charge-trapping sites 39E and a tunnel oxide layer 43 on the inner sidewall of the recess 24. The oxide layer 36 and the oxide layer 44 together form an insulation structure 46E surrounding the two charge-trapping sites 39E, and each of the charge-trapping site 39E and the insulation structure 46E surrounding the charge-trapping site 39E form a storage structure 45E. Subsequently, a polysilicon layer 48 doped with N-type dopants is formed by a deposition process followed by a planarization process such as the chemical mechanical polishing process, and a tungsten silicide layer 50 and a silicon nitride layer 52 are then formed on the polysilicon layer 48, as shown in FIG. 48.

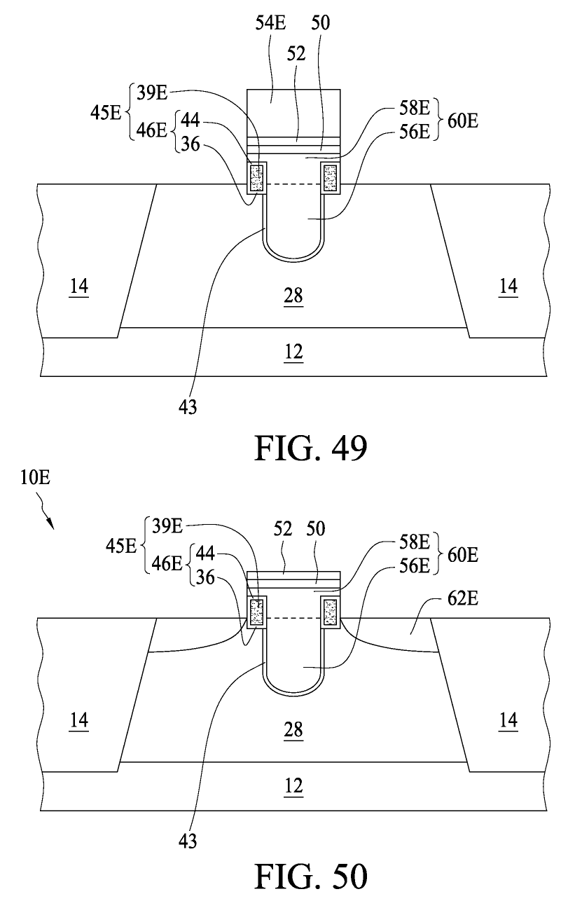

Referring to FIG. 49, a photoresist layer 54E is formed on the silicon nitride layer 52 by the lithographic process, and a dry etching process is then performed to remove a portion of the polysilicon layer 48, the tungsten silicide layer 50 and the silicon nitride layer 52 not covered by the photoresist layer 54E to form a T-shaped gate structure 60E. Subsequently, the photoresist layer 54E is stripped, and an implanting process is then performed to implant N-type dopants into the P-well 28 to form a plurality of doped regions 62E serving as the source and the drain at the sides of the T-shaped gate structure 60E so as to complete the multi-level flash memory 10E, as shown in FIG. 50.

In particular, the T-shaped gate structure 60E includes a lower block 56E in the P-well 28 of the semiconductor substrate 12 and an upper block 58E on the P-well 28 of the semiconductor substrate 12, and the upper block 58E connects the lower block 56E. The lower block 56E of the T-shaped gate structure 60E serves as a recessed gate, while the remaining polysilicon layer 48 and tungsten silicide layer 50 together with the upper block 58E form a word line. Furthermore, the doped regions 62E contact the insulation structure 46E. In addition, the charge-trapping site 39E includes an upper portion on the P-well 28 and a bottom portion in the P-well 28, i.e., the charge-trapping site 39E extends from the interior to the exterior of the semiconductor substrate 12. The multi-level flash memory 10E can use channel hot electron injection (CHEI) mechanism to conduct the programming of the cell, use the band-to-band (BTBT) hot hole enhanced injection (HHEI) mechanism to conduct the erasing of the cell, use the reversed read mechanism to conduct the reading of the cell.

As the size of the flash memory is reduced, the distance between the charge-trapping regions 140A and 140B of the conventional flash memory 100 may become too small, which in the prior art may result in merging of the charge-trapping regions 140A and 140B. In contrast, the storage structures 45E of the flash memory 10E are separated by the T-shaped gate structure 60E; therefore, the storage structures 45E are prevented from merging even as the size of the flash memory 10E is reduced.

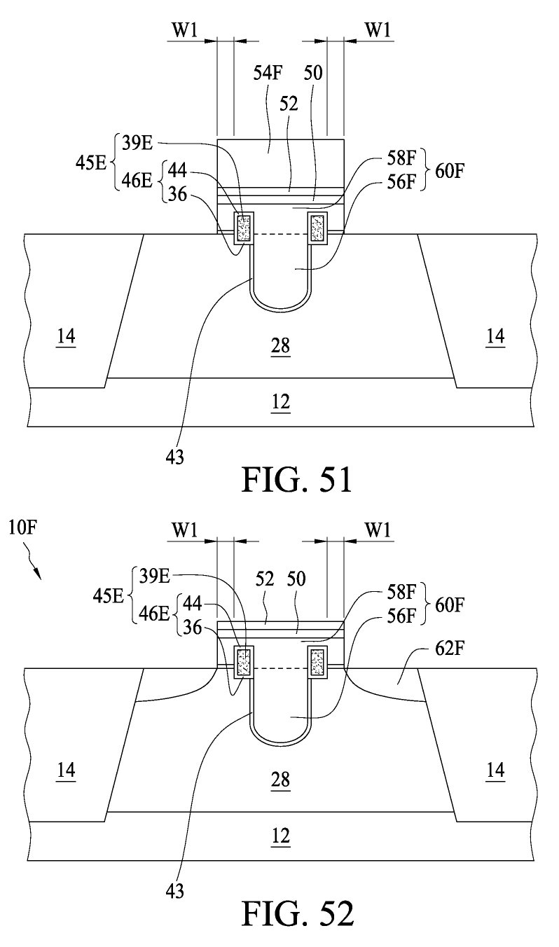

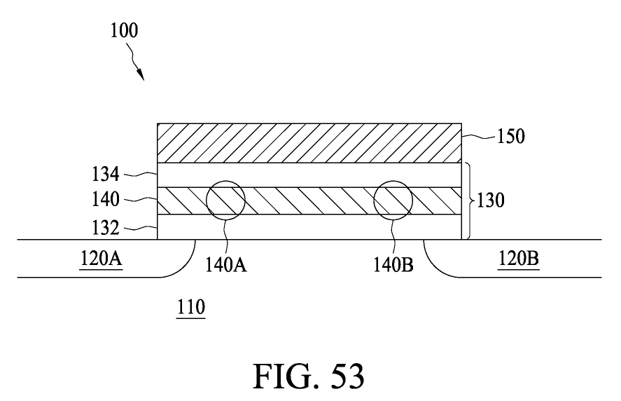

FIG. 51 and FIG. 52 illustrate a method for preparing a multi-level flash memory 10F according to another embodiment of the present invention. The fabrication processes shown in FIG. 36 to FIG. 48 are performed, a photoresist layer 54F is formed on the silicon nitride layer 52 by the lithographic process, and a dry etching process is then performed to remove a portion of the polysilicon layer 48, the tungsten silicide layer 50 and the silicon nitride layer 52 not covered by the photoresist layer 54F to form a T-shaped gate structure 60F including a lower block 56F in the semiconductor substrate 12 and an upper block 58F on the semiconductor substrate 12. Subsequently, the photoresist layer 54F is stripped, and an implanting process is then performed to implant N-type dopants into the P-well 28 to form a plurality of doped regions 62F serving as the source and the drain at the sides of the T-shaped gate structure 60F so as to complete the multi-level flash memory 10F, as shown in FIG. 52.

In particular, the lateral width of the photoresist layer 54F in FIG. 51 is larger than that of the photoresist layer 54E in FIG. 49 by 2×W1. Therefore, the lateral width of the T-shaped gate structure 60F in FIG. 51 is increased by 2×W1 as compared to that of the T-shaped gate structure 60E in FIG. 49. Consequently, the doped regions 62F are separated from the insulation structure 46E by the semiconductor substrate 12, and the channel length of the multi-level flash memory 10F in FIG. 52 is larger than that of the multi-level flash memory 10E in FIG. 50 by 2×W1. The multi-level flash memory 10E can use channel hot electron injection (CHEI) mechanism to conduct the programming of the cell, use the band-to-band (BTBT) hot hole enhanced injection (HHEI) mechanism to conduct the erasing of the cell, use the reversed read mechanism to conduct the reading of the cell.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A multi-level flash memory, comprising:
a semiconductor substrate;
a recessed gate positioned in the semiconductor substrate;
an oxide layer sandwiched between the recessed gate the semiconductor substrate; and
a plurality of storage structures separated by the recessed gate, with each of the storage structures including a charge-trapping site and an insulation structure surrounding the charge-trapping site.

2. The multi-level flash memory of claim 1, wherein the semiconductor substrate includes a well, and the charge-trapping site is positioned in the well.

3. The multi-level flash memory of claim 1, wherein the charge-trapping site includes silicon nitride or polysilicon.

4. The multi-level flash memory of claim 1, wherein the insulation structure includes silicon-oxy-nitride or silicon oxide.

5. The multi-level flash memories of claim 1, further comprising a plurality of doped regions positioned at the sides of a lower block and contacting to the insulation structure.

6. The multi-level flash memory of claim 1, further comprising a plurality of doped regions positioned at the sides of a lower block and separated from the insulation structure by the semiconductor substrate.

7. The multi-level flash memory of claim 1, further comprising a word line positioned on the recessed gate

8. The multi-level flash memory of claim 7, wherein the word line covers the storage structures.

9. A multi-level flash memory, comprising:
a semiconductor substrate;
a gate structure having a lower block positioned in the semiconductor substrate and an upper block positioned on the semiconductor substrate, with the upper block connecting to the lower block; and
a plurality of storage structures separated by the gate structure, with each of the storage structures including a charge-trapping site and an insulation structure surrounding the charge-trapping site.

10. The multi-level flash memory of claim 9, wherein the semiconductor substrate includes a well, and the charge-trapping site is positioned on the well.

11. The multi-level flash memory of claim 9, wherein the semiconductor substrate includes a well, and the charge-trapping site includes an upper portion on the semiconductor substrate and a bottom portion in the semiconductor substrate.

12. The multi-level flash memory of claim 9, wherein the semiconductor substrate includes a well, and the charge-trapping site extends from an interior to an exterior of the well.

13. The multi-level flash memory of claim 9, wherein the upper block of the gate structure covers the storage structures.

14. The multi-level flash memory of claim 9, wherein the charge-trapping site includes silicon nitride or polysilicon.

15. The multi-level flash memory of claim 9, wherein the insulation structure includes silicon-oxy-nitride or silicon oxide.

16. The multi-level flash memory of claim 9, further comprising a plurality of doped regions positioned at the sides of the lower block and contacting to the insulation structure.

17. The multi-level flash memory of claim 9, further comprising a plurality of doped regions positioned at the sides of the lower block and separated from the insulation structure by the semiconductor substrate.

18. The multi-level flash memory of claim 9, wherein the gate structure is T-shaped.
